(19) United States
(12) Patent Application Publication
(10) Pub. No.: US 2018/0138078 A1
(43) Pub. Date: May 17, 2018

(54) Method for Regulating Hardmask Over-Etch for Multi-Patterning Processes

(71) Applicant: Tokyo Electron Limited, Tokyo (JP)

(72) Inventors: Richard Farrell, Nassau, NY (US); Nihar Mohanty, Clifton Park, NY (US); Jeffrey Smith, Clifton Park, NY (US)

(21) Appl. No.: 15/815,371

(22) Filed: Nov. 16, 2017

Related U.S. Application Data
(60) Provisional application No. 62/422,825, filed on Nov. 16, 2016.

(51) Int. Cl. H01L 21/768; H01L 21/3213

(52) U.S. Cl. CPC H01L 21/7688; B82Y 40/00; H01L 21/3213

(57) ABSTRACT

Techniques herein include patterning processes to prevent over-etching for various multi-patterning processes. Multi-patterning processes typically involve creation of sidewall spacers and removal of mandrels on which sidewall spacers are formed. In some patterning flows gouging of underlying layers can occurs during the various multi-patterning steps. Techniques herein include methods to prevent such gouging by using a planarization layer recessed sufficiently to removed desired materials and protect others. Such techniques can remove bi-layer mandrels without gouging underlying layers.

### CROSS REFERENCE TO RELATED APPLICATIONS

The present application claims the benefit of U.S. Provisional Patent Application No. 62/422,825, filed on Nov. 16, 2016, entitled “Method for Regulating Hardmask Over-etch for multi-patterning processes,” which is incorporated herein by reference in its entirety.

### BACKGROUND OF THE INVENTION

This disclosure relates to etching features in substrates, including patterning processes for etching substrates.

The fabrication of integrated circuits (IC) in the semiconductor industry typically involves using a plasma reactor to create plasma that assists surface chemistry used to remove material from—and deposit material on—a substrate. Dry plasma etching processes are routinely used to remove or etch material along fine lines or within vias or at contacts patterned on a semiconductor substrate. A successful plasma etching process requires an etching chemistry that includes chemical reactants suitable for selectively etching one material while not etching another material (not substantially etching another material). Etching processes are typically used in conjunction with a patterned mask.

For example, on a semiconductor substrate a relief pattern formed in a protective layer can be transferred to an underlying layer of a selected material using a directional plasma etching process. The protective layer can comprise a light-sensitive layer, such as a photoresist layer, having a latent pattern formed using a lithographic process, and then this latent pattern can be developed into a relief pattern by dissolving and removing soluble portions of the photoresist layer. Once the relief pattern is formed, the semiconductor substrate is disposed within a plasma processing chamber, and an etching chemistry is formed that selectively etches the underlying layer while minimally etching the protective layer.

This etch chemistry is produced by introducing an ionizable, dissociative gas mixture having parent molecules comprising molecular constituents that react with the underlying layer while minimally reacting with the protective or patterning layer (etch mask). Production of the etch chemistry comprises introduction of a gas mixture and formation of plasma when a portion of the gas species present are ionized following a collision with an energetic electron. Heated electrons can serve to dissociate some species of the gas mixture and create a reactive mixture of chemical constituents (of the parent molecules). Accordingly, various substrate materials can be controllably removed or deposited using various patterning and etch processes.

### SUMMARY

Conventional production patterning approaches use immersion lithography with 193 nm wavelength light to create patterns. This approach is limited to about 80 nm pitch resolution. Achieving a smaller pitch is possible, but associated techniques lead to smaller process windows and patterning restrictions (such as used with 1D patterning only). NA (numerical aperture) 0.33 Extreme Ultraviolet (EUV) lithography can possibly extend pitch resolution to about 24 nm, but EUV tool complexities and costs associated with this technology are too great to be a viable solution. As another fabrication path, many multi-patterning options such as SADP (self-aligned double patterning) or SAQP (self-aligned quad patterning) have been proposed to provide the semiconductor industry with continued scaling at 14 nm nodes and beyond.

SAQP is a multi-patterning method that includes executing multiple iterations of pitch division from the pre-existing lithographic patterns. In a basic SAQP process flow, a conformal ALD film (known as spacer material) is deposited on photoresist or amorphous carbon layer (known as mandrel) to define a spacer pattern. The spacer material is etched back to remove spacer material on top of mandrels and create space between mandrels, resulting in what is known as sidewall spacers. Mandrels are then selectively removed (leaving sidewall spacers). The remaining sidewall spacers essentially form a relief pattern and are used as an etch mask to transfer the relief pattern into one or more underlying layers. The result of this patterning technique is dividing the pitch of the initial mandrels by a factor of two. This can also be considered as increasing a pattern density of the initial mandrels. Repeating this process enables another division of the pitch and is known as SAQP. Advantages of implementing an SAQP process include non-critical, single-pass lithography (relaxed pitch), self-aligned patterns that avoid more complex overlay as compared to litho-etch-litho-etch-litho-etch. Moreover, the final CD control is governed by the ALD process which provides Angstrom level control of CDs and the numerous iterations (etch, deposit) enable significant improvements in LER and LWR.

The spacer etch and etch transfer steps of such multi-patterning can be challenging—especially when material etch resistivities are not perfect. Imperfect etch resistivities can result in unwanted etching of underlying layers. Techniques herein, however, provide a method for minimizing plasma etch gouging into hard masks during various multi-patterning processing to overcome poor selectivity between stack and spacer materials. Such techniques can be applied to various multi-patterning applications including SAQP for BEOL (back-end-of-line) patterning applications

One example embodiment includes a method of patterning a substrate. A substrate is received having a relief pattern of mandrels. Each mandrel is comprised of a first layer of a first material and a second layer of a second material. The second layer being positioned on the first layer. Sidewall spacers are formed on sidewalls of the mandrels. The sidewall spacers having a mandrel side and a spacer side. The mandrel side is in contact with a given mandrel and the spacer side faces an adjacent sidewall spacer. In this configuration, adjacent sidewall spacers define open space between each other. A layer of fill material is deposited on the substrate that fills open spaces between sidewall spacers and that covers the mandrels and sidewall spacers. The layer of fill material is recessed until recessed below top surfaces of the mandrels and sidewall spacers. The second layer is removed from the mandrels such that remaining fill material is sufficient to prevent etching of an underlying layer while removing the second layer. The mandrels can then be removed from the substrate for additional patterning and/or pattern transfer to an underlying layer(s).

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete appreciation of various embodiments of the invention and many of the attendant advantages thereof will become readily apparent with reference to the following detailed description considered in conjunction with the accompanying drawings. The drawings are not necessarily to scale, with emphasis instead being placed upon illustrating the features, principles and concepts.

FIG. 1 is a cross-sectional schematic view of an example substrate segment showing a process flow according to embodiments disclosed herein.

FIG. 2 is a cross-sectional schematic view of an example substrate segment showing a process flow according to embodiments disclosed herein.

FIG. 3 is a cross-sectional schematic view of an example substrate segment showing a process flow according to embodiments disclosed herein.

FIG. 4 is a cross-sectional schematic view of an example substrate segment showing a process flow according to embodiments disclosed herein.

FIG. 5 is a cross-sectional schematic view of an example substrate segment showing a process flow according to embodiments disclosed herein.

FIG. 6 is a cross-sectional schematic view of an example substrate segment showing a process flow according to embodiments disclosed herein.

FIG. 7 is a magnified view of a substrate segment processed according to conventional techniques.

FIG. 8 is a magnified view of a substrate segment processed according to embodiments disclosed herein.

### DETAILED DESCRIPTION

Techniques herein include patterning processes to prevent over-etching for various multi-patterning processes. Multi-patterning processes typically involve creation of sidewall spacers and removal of mandrels on which sidewall spacers are formed. In some patterning flows gouging of underlying layers can occurs during the various multi-patterning steps. Techniques herein include methods to prevent such gouging by using a planarization layer recessed sufficiently to removed desired materials and protect others. Such techniques can remove bi-layer mandrels without gouging underlying layers.

SAQP patterning for FEOL (front-end-of-line) applications can be implemented using many different stack and deposition films (amorphous-Silicon, amorphous carbon at 600° C. etc.) because the maximum processing temperature can be approximately 700° C. in some integration schemes. In contrast, when SAQP is used for BEOL (back-end-of-line) applications, the maximum processing temperature is governed by the stability of the underlying low-k dielectric material and barrier materials. In current 14 nm node fabrication, the temperature cap is approximately 400° C. and it is projected that for the 7 nm node, the temperature cap will be closer to about 350° C. This creates a significant challenge to etch materials with sufficient selectivity.

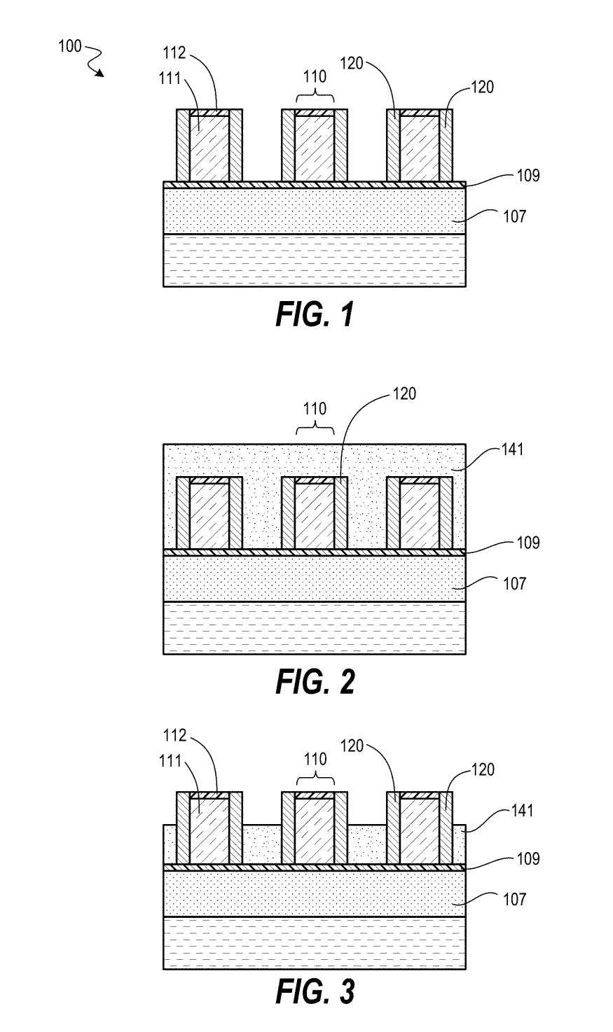

Techniques herein will now be described with reference to the accompanying drawings. One example embodiment includes a method of patterning a substrate. In FIG. 1, a substrate 100 is received having a relief pattern of mandrels 110. Each mandrel 110 is comprised of a first layer 111 of a first material and a second layer 112 of a second material. The second layer 112 is positioned on the first layer 111. Sidewall spacers 120 are formed on sidewalls of the mandrels 110. The sidewall spacers 120 have a mandrel side and a spacer side. The mandrel side in contact with a given mandrel and the spacer side faces an adjacent sidewall spacer in that adjacent sidewall spacers define open space between each other. In other words, after depositing a conformal spacer film and executing a spacer open etch, there are trenches on the substrate defined by a combination of the mandrels and the sidewall spacers.

The second layer 112 can be a silicon-containing anti-reflective coating formed as a film on top of first layer 111 prior to lithographic patterning to create mandrels 110. Thus the first layer 111 can be five or more times thicker than second layer 112. An exemplary SAQP process flow for a BEOL application uses lithography patterning performed with 193 nm dry or immersion photolithography. A low reflectivity portion of a corresponding substrate stack can be comprised of a silicon-containing anti-reflective coating (Si-ARC)/amorphous carbon (exemplary materials include ShinEtsu SHB-A940 silicon-containing ARC, Silicon-oxy-nitrides and APF from Applied Materials patterning film, or ShinEtsu spin-on organic planarizing layer) as a mandrel feature.

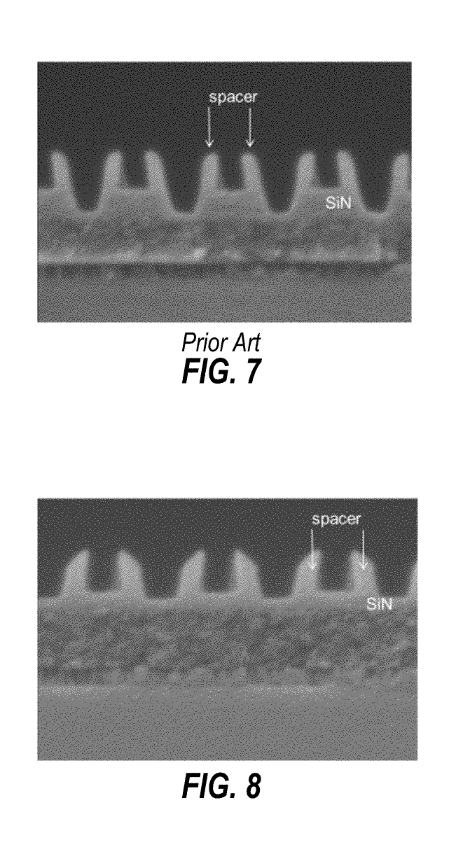

Mandrels 110 and sidewall spacers 120 can be formed on underlying layer 109. Target layer 107 can function as a memorization layer. Spacer material can be deposited, for example, by ALD (atomic layer deposition) for a conformal coating. One example spacer material includes silicon dioxide (SiO2). The conformal coating can then be etched back to reveal or uncover the SiARC/mandrel (also known as a core) and also to reveal underlying layer 109, which can be silicon nitride (SiN) which defines the gap between adjacent sidewall spacers. This layer can be less than 40 nanometers in vertical thickness. The underlying layer 109 can have an etch resistivity insufficient to prevent etching for a particular etch chemistry used to remove the second layer 112 of the mandrels by etching. In other words, when the SiARC is removed from the top of the mandrels, the uncovered silicon nitride layer can be etched as well as target layer 107. An example is shown in FIG. 7. Note that mandrels have been removed leaving spacers, but the underlying SiN layer has been significantly etched.

To reveal desirable spacer features, the SiARC and amorphous carbon must be removed (“pulled out”). Such removal, however, is challenging because the materials SiN, SiO2 and SiARC, all have very similar etch selectivities (resistivities). As such, SiARC removal typically results in unwanted etching (known as gouging) into hardmask material. For example, silicon nitride is undesirably etched during SiARC removal.

As previously noted, a maximum temperature for BEOL processing can be specified (for some microfabrication flows) as 400° C., and this maximum is decreasing with subsequent technology nodes. Such a maximum temperature affects processing of other materials. For example, using a relatively higher temperature during deposition of a given thin film can help to densify a deposited film, which is beneficial for some fabrication flows. A consequence of a temperature cap, however, can result in a deposited silicon nitride being considered “soft” in terms of etch resistance, especially for certain BEOL applications due to similar etch resistivities with Si-ARC. Etching then can result in significant gouging or over-etching into the silicon nitride (sometimes referred to as burn-off). In some flows it is specified to have a relatively thin (approximately 20-30 nm) hardmask to better enable subsequent processing. With conventional flows, however, a tendency for over-etch and additional gouging into a carbon underlayer is very likely and will subsequently provide poor process window and process margin for high-volume manufacturing.

Techniques herein, however, prevent such gouging or over-etching. Referring now to FIG. 2, a layer of fill material 141 is deposited on the substrate. The fill material 141 fills open spaces between sidewall spacers and covers the mandrels and sidewall spacers. Such a fill material can be deposited by spin-on deposition using a coater-developer (Track) tool. The fill material can be an organic material that essentially covers the topography and planarizes the substrate.

Next, the layer of fill material 141 is recessed until a top surface of the fill material 141 is below top surfaces of the mandrels and sidewall spacers. A result is shown in FIG. 3. Such recessing can be executed as an etch process such as with a dry, plasma-based etch process to uncover spacer tips and the anti-reflective coating on top of the mandrels. In other embodiments, the recess etch can be executed on track tools using air and UV treatment to produce ozone to remove organic films. This etch process can be executed at less than 400 degrees Celsius. Note that a portion of the fill material remains to protect underlying layer 109, which can be a hardmask layer and/or low-stress silicon nitride film. This fill material protection can be beneficial when the underlying layer has an etch resistivity insufficient to prevent etching for a particular etch chemistry used to remove the second layer of the mandrels by etching.

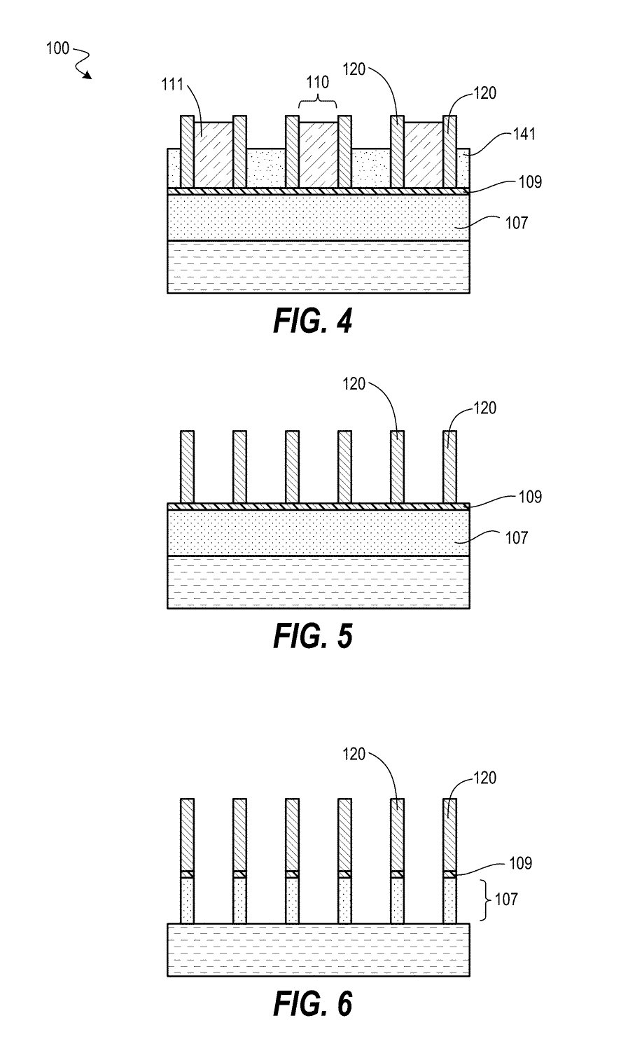

Next, the second layer is removed from the mandrels such that remaining fill material is sufficient to prevent etching of an underlying layer while removing the second layer (FIG. 4). Such removal can be executed in a same plasma processing chamber as used for recessing the fill material. Plasma etch chemistry can be switched to remove the second layer (such as a SiARC layer).

The mandrels (first layer) can then be removed. In some embodiments, the remaining mandrel material can be removed simultaneously with the fill material. For example, if the bulk mandrel material is amorphous carbon and the fill material is organic, then an ashing process can be used to remove both (FIG. 5). The substrate can then be used with additional multi-patterning or pattern transfer. FIG. 6 illustrates transferring the spacer pattern into underlying layer 109 and target layer 107. FIG.8 is a magnified image (electron micrograph) of a substrate processed according to techniques herein. Note that the SiN underlying layer is protected through the processes of spacer formation and mandrel removal.

Results of techniques herein include well-defined spacer features with minimal gouging into the hardmask. In addition, the process margin for the OPL etch-back is improved over conventional processes. Benefits of OPL overcoat and etch back techniques herein include minimizing plasma etch gouging into soft, low temperature (<350 C) hardmasks and avoiding downstream CD bias/pitch walking complications in an SADP/SAQP flow. Another benefit is that more materials can be used such as soft, low-temperature (less than 350° C.) materials that otherwise could not be deposited. Soft, low-temperature materials can also be used as hardmasks. There is a reduced need to use high temperature hardmask films within the SAQP stack especially with a thermal limit for underlying BEOL dielectric films being greater than 300° C. Techniques herein can be used for each spacer formation process in multi-patterning schemes. Techniques can also help improve spacer profile/shape.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method of patterning a substrate, the method comprising:
receiving a substrate having a relief pattern of mandrels, each mandrel comprised of a first layer of a first material and a second layer of a second material, the second layer being positioned on the first layer;
forming sidewall spacers on sidewalls of the mandrels, the sidewall spacers having a mandrel side and a spacer side, the mandrel side in contact with a given mandrel and the spacer side facing an adjacent sidewall spacer in that adjacent sidewall spacers define open space between each other;
depositing a layer of fill material on the substrate that fills open spaces between the sidewall spacers and covers the mandrels and the sidewall spacers;
recessing the layer of fill material until recessed below top surfaces of the mandrels and the sidewall spacers; and
removing the second layer from the mandrels such that remaining fill material is sufficient to prevent etching of an underlying layer while removing the second layer; and
removing the mandrels from the substrate.

2. The method of claim 1, wherein recessing the layer of fill material includes executing an etch process.

3. The method of claim 2, wherein the layer of fill material is organic material.

4. The method of claim 2, wherein the etch process executed at less than 400 degrees Celsius.

5. The method of claim 1, further comprising:
removing remaining fill material from the substrate.

6. The method of claim 5, further comprising:
transferring a relief pattern defined by the sidewall spacers into the underlying layer.

7. The method of claim 1, wherein the underlying layer has an etch resistivity insufficient to prevent etching for a particular etch chemistry used to remove the second layer of the mandrels by etching.

8. The method of claim 1, wherein the underlying layer is less than 40 nanometers in vertical thickness.

9. The method of claim 8, wherein the underlying layer comprises silicon nitride.

10. The method of claim 8, wherein the second layer is a silicon-containing anti-reflective coating.

11. The method of claim 1, wherein the second layer is formed as a film on a top surface of the first layer.

12. The method of claim 11, wherein the second layer has a vertical thickness at least five times greater than the second layer.
